(19) United States
(12) Patent Application Publication
(10) Pub. No.: US 2022/0318469 A1
(43) Pub. Date: Oct. 6, 2022

(54) Systems, Methods, and Devices for Virtual Prototyping

(71) Applicant: Sahara Cloud, Inc., Los Angeles, CA (US)

(72) Inventors: Jama Mohamed, Los Angeles, CA (US); Joshua Kimmel, San Ramon, CA (US)

(21) Appl. No.: 17/707,734

(22) Filed: Mar. 29, 2022

Related U.S. Application Data
(60) Provisional application No. 63/170,770, filed on Apr. 5, 2021.

(51) Int. Cl. G06F 30/3308

(52) U.S. Cl. CPC G06F 30/3308

(57) ABSTRACT

Systems, methods, and devices for virtual prototyping in accordance with embodiments of the invention are disclosed. In one embodiment, a non-transitory machine readable storage medium storing a program is provided, comprising instructions that, when executed by at least one processor of at least one server, cause the server(s) to perform operations including: receiving, at the server(s), from a client device, architecture data comprising a selection of a hardware device for virtual prototyping; generating job order data, wherein the job order data provides logical provisioning of at least one hardware device; transmitting, from the server(s), to the at least one hardware device, the job order data; receiving, at the server(s), from the at least one hardware device, hardware output data; and transmitting, from the server(s), to the client device, the hardware output data.

### CROSS-REFERENCE TO RELATED APPLICATION

The current application claims priority to U.S. Provisional Patent Application No. 63/170,770, filed on Apr. 5, 2021, the disclosure of which is incorporated herein by reference.

### FIELD OF THE INVENTION

The present invention generally relates to electronics and more specifically to systems, methods, and devices for virtual prototyping.

### BACKGROUND

Printed circuit boards (PCBs) are boards configured for connecting various electronic components together. Typically, PCBs include a card that is made of a material that does not conduct electricity (e.g., fiberglass) and are etched with a medium (e.g., copper) that allows electricity to move between one or more of the electronic components that are attached to the board. PCBs may include a variety of different parts which may be connected and work together. Further, PCBs may be used for designing and manufacturing devices in various fields such as automotive, healthcare, building and construction equipment, communication devices, etc.

### SUMMARY OF THE INVENTION

The various embodiments of the present virtual prototyping and/or digital twinning (may be collectively referred as “virtual prototyping”) contain several features, no single one of which is solely responsible for their desirable attributes. Without limiting the scope of the present embodiments, their more prominent features will now be discussed below. In particular, the present systems, methods, and devices for virtual prototyping will be discussed in the context of field-programmable gate arrays (FPGAs). However, the use of FPGAs is merely exemplary and various other integrated circuits may be utilized for virtual prototyping as appropriate to the requirements of a specific application in accordance with embodiments of the invention. After considering this discussion, and particularly after reading the section entitled “Detailed Description,” one will understand how the features of the present embodiments provide the advantages described here.

One aspect of the present embodiments includes the realization that there may be a lack of access to physical equipment for a variety of reasons. For example, users (e.g., software developers, engineers, etc.) (may also be referred to as “developers”) may lack access to physical boards, sensors, and test equipment. The current embodiments provide for virtual prototyping in the cloud allowing users to start research and development (R&D) immediately without needing to purchase physical components. In many embodiments, a user may develop and/or provide source code (may also be referred to as “code”). For example, the user may develop and/or provide code via a web browser. In some embodiments, the user may develop and/or provide code without the need to download any additional software. In various embodiments, the virtual prototyping platforms may allow developers to remotely connect to circuit boards, chips, and test equipment in the cloud. In a variety of embodiments, developers may build electronic circuits remotely and with less risk, making product development more accessible. Thus, developers may code and test on remote electronics as if they were physically present.

Another aspect of the present embodiments includes the realization that product development may be a difficult task. Not only do product developers need to know how to code, but they may also need to know how to design and fabricate electronic circuit boards. While software developers can write the code themselves for free, hardware and electronic development may take significantly more time and money, even for a first prototype. Rather than focusing on the immediate value they can create by working on software development, developers may expend enormous effort setting up the physical environment. Many times, engineers may get frustrated and quit. The current virtual prototyping platforms may include aspects such as, but not limited to, building, coding, and testing of virtual prototypes. For example, developers may select a combination of different sensors, chips and processors to target, effectively building a virtual hardware system, as further described below. In addition, developers may write code for that virtual hardware system through a web-based integrated development environment (IDE), with access to one or more application programming interfaces (APIs) providing various testing features, as further described below. Moreover, hardware outputs such as voltages, currents, and other low-level electrical information may be captured and made available to the user throughout the testing process as normally as would be in reality. In many embodiments, virtual prototyping platforms may be accessible via various tools such as, but not limited to, extensions to Visual Studio (VS) Code, allowing developers to continue using the tools that they may already utilize, as further described below. In various embodiments, virtual prototyping platforms may allow developers to build electronic circuits in a distributed manner and may be offered to a large number of concurrent users.

Another aspect of the present embodiments includes the realization that in the hardware industry, there is no comprehensive solution for virtual development. Indeed, the work and training is largely still done by hand, at a lab workbench, with physical parts necessary. To solve this problem, present embodiments provide a fundamental shift in thinking around product development. For example, electronic design does not need to be bounded by the physicality of the products themselves. Thus, the R&D process for products does not need to start with circuit board fabrication or chip procurement. The present embodiments provide comparable and/or the same electronic system a developer would physically make, but do it in the cloud and provide remote access. In many embodiments, users may get their projects off the ground faster, and get to writing software and iterating in a matter of minutes, rather than months.

In a first aspect, a non-transitory machine readable storage medium is provided, the non-transitory machine readable storage medium storing a program comprising instructions that, when executed by at least one processor of at least one server, cause the server(s) to perform operations including: receiving, at the server(s), from a client device, architecture data comprising a selection of a hardware device for virtual prototyping; generating job order data, wherein the job order data provides logical provisioning of at least one hardware device; transmitting, from the server(s), to the at least one hardware device, the job order data; receiving, at the server(s), from the at least one hardware device, hardware output data; and transmitting, from the server(s), to the client device, the hardware output data.

In an embodiment of the first aspect, the logical provisioning of the at least one hardware device includes configuring the at least one hardware device to run a job.

In an embodiment of the first aspect, the non-transitory computer readable storage medium further comprises instructions that, when executed by the at least one processor, further cause the server(s) to receive, at the server(s), from the client device, code data to run on the at least one hardware device.

In an embodiment of the first aspect, the job order data comprises the code data.

In an embodiment of the first aspect, the non-transitory computer readable storage medium further comprises instructions that, when executed by the at least one processor, further cause the server(s) to identify a target architecture associated with the at least one hardware device and compile the code data such that it can run on the target architecture.

In an embodiment of the first aspect, the job order data comprises the compiled code data.

In an embodiment of the first aspect, the non-transitory computer readable storage medium further comprises instructions that, when executed by the at least one processor, further cause the server(s) to receive, at the server(s), from the client device, test data comprising information about test output to track.

In an embodiment of the first aspect, the job order data comprises the test data.

In an embodiment of the first aspect, the hardware output data received from the at least one hardware device is raw output data.

In an embodiment of the first aspect, the non-transitory computer readable storage medium further comprises instructions that, when executed by the at least one processor, further cause the server(s) to format the raw output data prior to transmitting, from the server(s), to the client device, the hardware output data.

In an embodiment of the first aspect, formatting the raw output data comprises: placing the raw output data in a buffer; sequencing the raw output data based on metadata associated with the raw output data to correct for re-ordering; compressing the sequenced raw output data; and storing the sequenced raw output data in a storage.

In an embodiment of the first aspect, the at least one hardware device includes at least one FPGA.

In an embodiment of the first aspect, the job order data comprises pin mappings for configuring the at least one FPGA.

In an embodiment of the first aspect, the at least one hardware device includes at least one bare-metal device.

In an embodiment of the first aspect, the non-transitory computer readable storage medium further comprises instructions that, when executed by the at least one processor, further cause the server(s) to procure the at least one bare-metal device based on physical proximity of the at least one bare-metal device to the server(s).

In an embodiment of the first aspect, the non-transitory computer readable storage medium further comprises instructions that, when executed by the at least one processor, further cause the server(s) to procure the at least one bare-metal device based on a maximum number of current users of the at least one bare-metal device, wherein the at least one bare-metal device includes a lock whereby only one user can use the at least one bare-metal device for a given time interval.

In an embodiment of the first aspect, the at least one hardware device includes at least one simulated device.

In an embodiment of the first aspect, the at least one hardware device includes at least one emulated device.

In an embodiment of the first aspect, the at least one hardware device further includes at least one emulated device and at least one simulated device.

In an embodiment of the first aspect, the at least one hardware device further includes at least one bare-metal device and at least one simulated device.

In an embodiment of the first aspect, the at least one hardware device further includes at least one bare-metal device, at least one simulated device, and at least one emulated device

In an embodiment of the first aspect, the at least one hardware device further includes at least one bare-metal device and at least one emulated device.

In an embodiment of the first aspect, the non-transitory computer readable storage medium further comprises instructions that, when executed by the at least one processor, further cause the server(s) to procure the at least one hardware device by transmitting, from the server(s), to a network of hardware devices, queries to capture the current state of the at least one hardware device and to obtain a lock when the at least one hardware device is available.

In an embodiment of the first aspect, the non-transitory computer readable storage medium further comprises instructions that, when executed by the at least one processor, further cause the server(s) to prioritize a job based on user-level metadata and job-level metadata.

### BRIEF DESCRIPTION OF THE DRAWINGS

The various embodiments of the present virtual prototyping platforms now will be discussed in detail with an emphasis on highlighting the advantageous features. These embodiments depict the novel and non-obvious virtual prototyping platforms shown in the accompanying drawings, which are for illustrative purposes only. These drawings include the following figures:

FIG. 1 is a block diagram illustrating a system for virtual prototyping in accordance with an embodiment of the invention;

FIG. 2 is a block diagram illustrating a client device for virtual prototyping in accordance with an embodiment of the invention;

FIG. 3 is a block diagram illustrating a virtual prototyping management server in accordance with an embodiment of the invention;

FIG. 4 is a flow chart illustrating a process for a client device in virtual prototyping in accordance with an embodiment of the invention;

FIG. 5 is a flow chart illustrating a process for a server in accordance with an embodiment of the invention;

FIG. 6 is a flow chart illustrating a process for a hardware device in accordance with an embodiment of the invention;

FIG. 7 is a diagram illustrating user access to a virtual prototyping platform in accordance with an embodiment of the invention;

FIG. 8 is a diagram illustrating a virtual prototyping platform in accordance with an embodiment of the invention;

FIG. 9 is a diagram illustrating a device provisioning system in accordance with an embodiment of the invention;

FIG. 10 is a diagram illustrating emulated and bare-metal devices in accordance with an embodiment of the invention;

FIG. 11 is a diagram illustrating a bare-metal FPGA interface in accordance with an embodiment of the invention;

FIG. 12 is a diagram illustrating a hybrid bare-metal/emulation FPGA interface in accordance with an embodiment of the invention;

FIG. 13 is a diagram illustrating simulated devices in accordance with an embodiment of the invention;

FIG. 14 is a diagram illustrating a device network in accordance with an embodiment of the invention;

FIG. 15 is a diagram illustrating a build system in accordance with an embodiment of the invention;

FIG. 16 is a diagram illustrating test data collection in accordance with an embodiment of the invention; and

FIG. 17 is a diagram illustrating test data stimulus in accordance with an embodiment of the invention.

### DETAILED DESCRIPTION OF THE DRAWINGS

The following detailed description describes the present embodiments with reference to the drawings. In the drawings, reference numbers label elements of the present embodiments. These reference numbers are reproduced below in connection with the discussion of the corresponding drawing features.

The embodiments of the present virtual prototyping platforms are described below with reference to the figures. These figures, and their written descriptions, may indicate that certain components of the apparatus are formed integrally, and certain other components are formed as separate pieces. Those of ordinary skill in the art will appreciate that components shown and described herein as being formed integrally may in alternative embodiments be formed as separate pieces. Those of ordinary skill in the art will further appreciate that components shown and described herein as being formed as separate pieces may in alternative embodiments be formed integrally. Further, as used herein the term integral describes a single unitary piece.

Turning now to the drawings, systems, methods, and devices for virtual prototyping in accordance with embodiments of the invention are described. In many embodiments, virtual prototyping platforms may allow one or more users to develop code on hardware via the user's client device (may also be referred to as “user device”), as further described below. In many embodiments, the present embodiments of virtual prototyping platforms provide improvements in the product life cycle. For example, the present embodiments may provide for the virtualization of traditional physical prototyping (may also be referred to as “virtutyping” or “virtual prototyping”) and/or the mirroring of a real system virtually (may also be referred to as “digital twinning”), as further described below. In several embodiments, virtutyping may include a digital product that has been physically prototyped virtually, as further described below.

Virtutypes provide benefits over traditional physical prototypes such as, but not limited to, overcoming the need for a physical lab setup, coupling of electrical engineering developmental bugs with software bugs, inability to share physical system with remote team members, etc. However, virtutyping benefits include, but are not limited to, no need for a physical lab setup, repeatable replication of debugging conditions on hardware (hermetic), collaboration on a shared system as it evolves, zero component lead-time, etc. Through virtual prototype platforms, developers may select physical devices that their code will run on at the chip level. This may be extremely valuable for software engineers, because they will not be limited by the hardware and electrical engineering skills they may lack. In many embodiments, virtual prototyping platforms may allow users to develop in phases such as, but not limited to, (1) architecture (select a device/devices to work on) where developers can select a combination of different sensors, chips, and processors on a web interface, (2) programming (code on devices) where a coding interface (text editor) may be available for every chip in the developer's architecture, code may be compiled and built on servers, faster than would happen on a user's local computer, and/or debugging flows and capabilities, (3) testing (test on devices) where data from real-world measurements (voltages, currents, etc.) may be saved so that automated software can monitor and catch bugs on a continual basis, tests may be replicable and hermetic (the same initial test conditions every time).

Virtual prototyping platforms may also allow for digital twinning. The problems inherent to digital product development persist beyond just the initial R&D. Even after a product has been launched into the market, product improvements and iterations may take time. Many times, new problems with the product emerge that only become obvious when deployed in large scale environments. These problems can be hard to replicate and solve in reality because the exact failure conditions cannot be easily replicated. This is where digital twinning may provide a solution. Virtual prototyping platforms in accordance with embodiments of the invention provide a way for developers to improve and manage prototypes throughout the lifecycle of a product, not just at its conception. For example, virtual prototype platforms may allow developers to take bugs found and inject test conditions into the digital twin, replicating the exact conditions. A wide array of data such as weather conditions, location history, communication delays, and more can be used as information. Further, testing may be hermetic, providing developers both enormous scale and high granularity. This ensures repeatability and speeds up development. This is the application of incremental improvements and large scale testing to hardware. In addition, continuous integration/continuous delivery based on real world pin inputs/outputs and data allows for safer upgrades and more insight into past bugs. Regression testing may happen at every step.

With recent developments in FPGA technology and the current systems, methods, and devices described herein, fully configurable cloud-based test systems have become a reality. In various embodiments, virtual prototype platforms allow control of various hardware devices and create a platform that is configurable, able to be updated in real-time, and is able to be shared amongst multiple users. As further described below, on the back end, virtual prototype platforms may include and/or host data centers full of different types of hardware devices such as, but not limited to, Arduinos, Raspberry Pis, and FPGA boards, as well as custom chips, processors, and sensors. In several embodiments, these individual devices may be monitored and provisioned by management systems (may also be referred to as “management server”), which allows the user to access that hardware remotely. When users run their code, data may be streamed back and forth in real time, facilitating automated testing and rapid development. Furthermore, the infrastructure of the virtual prototyping platforms may allow developers to create full systems of interconnected chips, allowing for full system testing and integration in the cloud.

In various embodiments, virtual prototyping platforms may allow a synergistic line of capabilities for users, such as, but not limited to access to integrated circuits (IC)—Bare-metal, where the infrastructure allows for the detailed control and orchestration of any IC. This makes adding new chips and sensor offerings to the system extremely easy. Another capability may include FPGA emulation where the virtual prototyping platforms create FPGA IP to emulate certain sensors and generic ICs. This enables lower cost emulation for users earlier in their development cycle without any switching costs. In addition, another capability may include personal computer (PC) simulation where the virtual prototyping platforms may host simulation tools to quickly run and check algorithms and/or processes that don't require emulation or bare-metal hardware. Since much of the hardware is software controlled, combinations of simulated, emulated, and bare-metal systems may be run concurrently based on users' development goals. Furthermore, another capability may include server access where the virtual prototyping platforms may host build servers to compile both software and hardware description language (HDL) faster than users' local computers. Moreover, another capability may include testing where the virtual prototyping platform may include software to generate test input and process test output.

In several embodiments, multi-tenancy techniques may allow the virtual prototyping platforms to host multiple developers on the same piece of hardware, pushing cost structure towards a traditional software business. In addition, a load balancing system may manage the different hardware devices in datacenters and abstracts it for the users, as further described below. Each user may be routed to their own development system and may be given a slice of time based on their project requirements. Systems for virtual prototyping platforms in accordance with embodiments of the invention are further described below.

### Virtual Prototyping Platform Systems

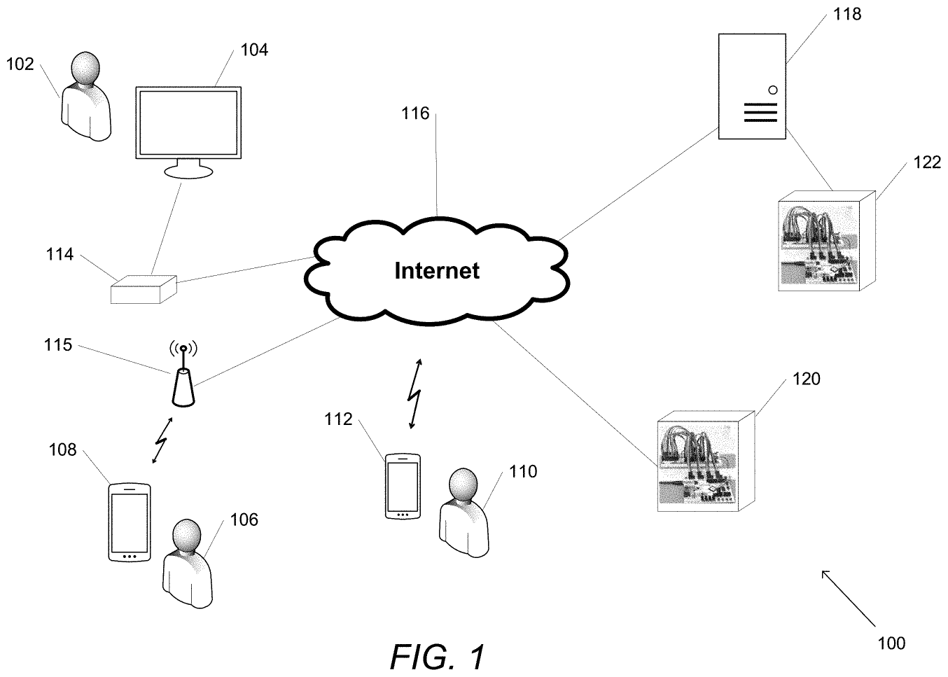

A block diagram illustrating a system for virtual prototyping in accordance with an embodiment of the invention is shown in FIG. 1. A virtual prototyping system 100 may include a first user 102 on a first client device 104 and/or a second user 106 on a second client device 108. In many embodiments, the first user 102 and/or the second user 106 may provide prototyping information (may also be referred to as “prototyping data”) such as, but not limited to, architecture information (may also be referred to as “architecture data”), code information (may also be referred to as “code data”), and/or test information (may also be referred to as “testing data”), as further described below. In some embodiments, the system 100 may also include additional users on additional client devices, such as, but not limited to, a third user 110 on a third client device 112. In various embodiments, the system 100 may include any number of users each having their own client device. In many embodiments, the client device(s) 104, 108, 112 may include various electronic devices that may receive a user's input, such as, but not limited to, a desktop computer, laptop computer, tablet computer, smart phone, etc.

In reference to FIG. 1, the client devices 104, 108, 112 may be connected to and have access to the Internet 116 in a manner known to one of ordinary skill in the art. For example, the first client device 104 may access the Internet 116 using a modem and/or router 114. Further, the second client device 108 may access the Internet 116 via a wireless access point 115, such as, but not limited to, Wi-Fi. Moreover, the third client device 112 may access the Internet 116 using a cellular network. In various embodiments, the client devices 104, 108, 112 may transmit their respective prototyping data (e.g., architecture data, code data, test data, etc.) to a virtual prototyping management server 118, as further described below.

In further reference to FIG. 1, the system 100 may also include a virtual prototyping management server 118 in network communication with at least one hardware device 120, 122, (e.g., FPGA) (may also be referred to as a “peripheral device”), as further described below. In some embodiments, the at least one hardware device 120 may be located separately from the management server 118 and in network communication (wireless or wired) via the Internet 116. In some embodiments, the at least one hardware device 122 may be directly (wireless and/or wired) connected to and in direct communication with the management server 118. In some embodiments, the at least one hardware device 122 may be part of the management server 118. The system 100 may also include any number of additional hardware devices connected to and/or in communication with the management server 118, as further described below. In many embodiments, the at least one hardware devices 120, 122 may include and/or be represented by simulated devices and/or emulated devices, as further described below.

In further reference to FIG. 1, the management server 118 may receive prototyping data from the client device(s) 104, 108, 112 and process the prototyping data and generate job instructions (may also be referred to as “job order” or “job order data”) for the hardware device(s) 120, 122, as further described below. In many embodiments, the at least one hardware device(s) 120, 122 may execute the job order and generate hardware output data, as further described below. In various embodiments, the at least one hardware device(s) 120, 122 may transmit the hardware output data to the management server 118, as further described below. In a variety of embodiments, the management server 118 may transmit the hardware output data to a client device (e.g., client device(s) 104, 108, 112), as further described below. In various embodiments, at least one hardware device(s) 120, 122 may transmit the hardware output data directly to at least one hardware device(s) 120, 122, as further described below.

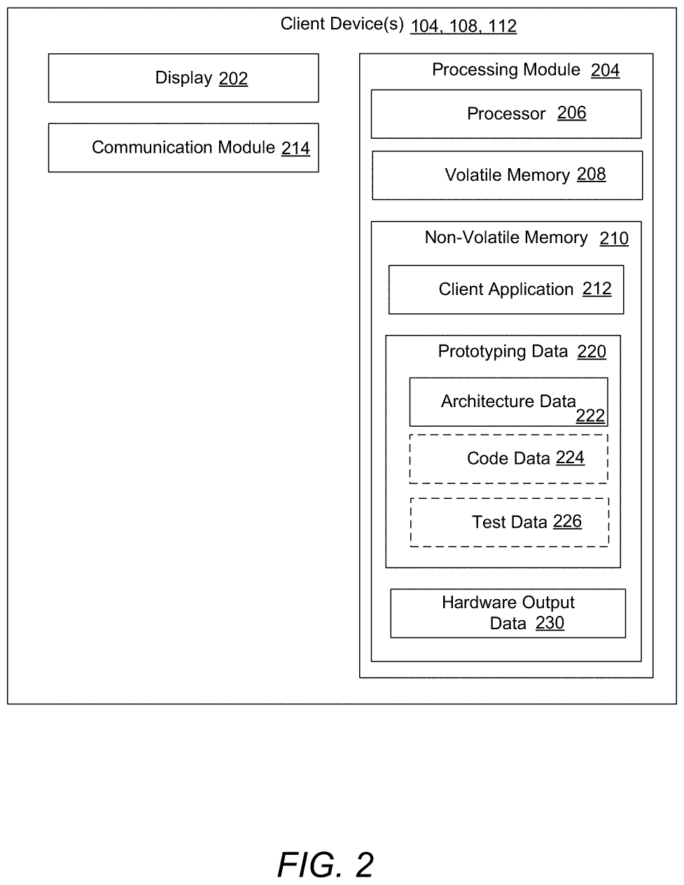

A block diagram illustrating a client device for virtual prototyping in accordance with an embodiment of the invention is shown in FIG. 2. In many embodiments, client device(s) 104, 108, 112 may be configured to obtain and transmit information from a user for virtual prototyping. In addition, client device(s) 104, 108, 112 may be configured to receive hardware output data, as further described herein. In many embodiments, a client device(s) 104, 108, 112 may include a processing module 204 that is operatively connected to a display 202 and a communication module 214. The processing module 204 may comprise a processor 206, volatile memory 208, and non-volatile memory 210. The non-volatile memory 210 may include a client application 212 that configures the processor 206 to perform various functions for virtual prototyping, as further described below. For example, the client device(s) 104, 108, 112 may obtain prototyping data 220, such as, but not limited to, architecture data 222, code data 224, and/or test data 262, as further described below.

In some embodiments, the client device(s) 104, 108, 112, may transmit the prototyping data 220 to the management server 118 using the communication module 214, as further described below. In some embodiments, the client device(s) 104, 108, 112 may receive hardware output data 230 using the communication module 214, as further described below. In many embodiments, the client device(s) 104, 108, 112 may also store the prototyping data 220 such as, but not limited to, the architecture data 222, the code data 224, and/or the test data 226, and the hardware output data 230 in the non-volatile memory 210. In some embodiments, the client device(s) 104, 108, 112 may be configured to present (e.g., visualize) the hardware output data 230 to the user of the client device(s) 104, 108, 112 using the display 202. In some embodiments, the hardware output data 230 may include, but is not limited to, waveforms on one or more configured input/output (I/O) channel(s) and/or simulated peripheral device(s) representing visual outputs, as further described below.

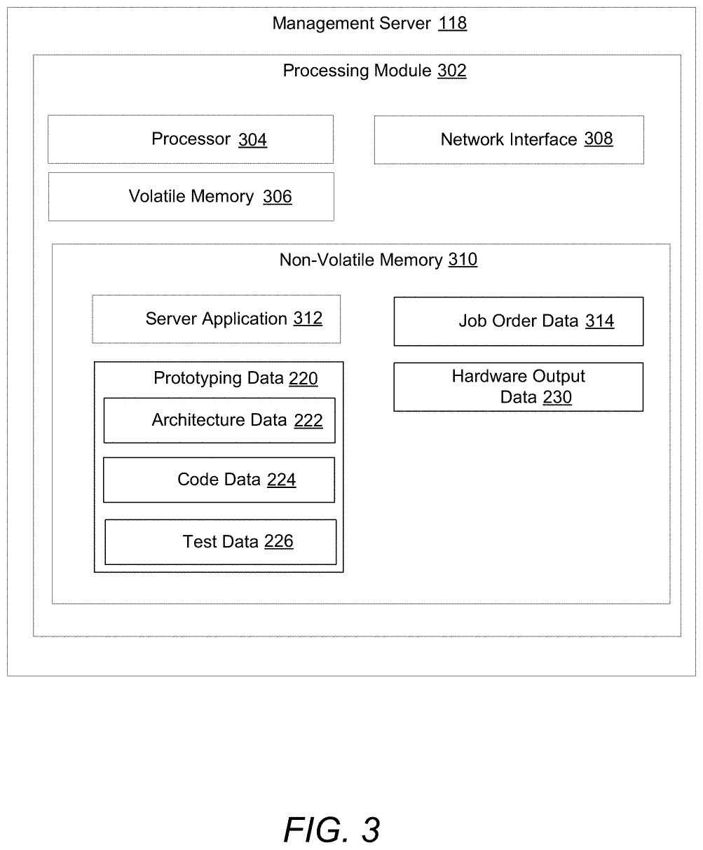

A block diagram illustrating a virtual prototyping management server in accordance with an embodiment of the invention is shown in FIG. 3. The virtual prototyping management server 118 may comprise a processing module 302 comprising a processor 304, volatile memory 306, and non-volatile memory 310. The processor 304 may be operatively connected to a network interface 308 that may allow the virtual prototyping management server 118 to access and communicate with devices connected to the network (Internet/PSTN) 116 for virtual prototyping, as described herein. For example, the non-volatile memory 310 may include a server application 312 that configures the processor 304 to receive data such as, but not limited to, prototyping data 220, architecture data 222, code data 224, and/or test data 226 from the one or more client device(s) 104, 108, 112. Further, the server application 312 may also configure the processor 306 to process the data 220, 222, 224, 226, received from the client device(s) 104, 108, 112, to generate data such as, but not limited to, job order data 314, as further described below. In many embodiments, the server 118 may transmit the job order data 314 to one or more hardware device(s) 120, 122 and receive hardware output data 230 from the one or more hardware device(s) 120, 122, as further described below.

In reference to FIG. 3, the server application 312 may configure the processor 304 to process information and drive the one or more hardware device(s) 120, 122 using APIs, as further described below. Although described in the context of a management server 118 (may also be referred to as “software backend”), one of ordinary skill in the art would appreciate that the functions and/or processes described herein as being performed by the management server 118 may be performed using software running on any suitable device. For example, a software backend may utilize a Job API to interface with the client device(s) 104, 108, 112 to initiate jobs. In some embodiments, a software backend may utilize a Device API to assigns the one or more hardware device(s) 120, 122 to jobs. In some embodiments, a software backend may utilize a Network API that allows the software backend to communicate with the one or more hardware device(s) 120, 122 to run jobs. In some embodiments, a software backend may utilize a Collector service to capture the hardware output data 230 (may also be referred to as “hardware digital output”). In some embodiments, a software backend may utilize an Output API to interface with the client device(s) 104, 108, 112 to allow the user to view the job output.

In many embodiments, the one or more hardware device(s) 120, 122 (may also be referred to as “hardware backend”) may receive a job order from the server 118. In various embodiments, the hardware device(s) 120, 122 may be configured to run a user's job(s) on a selected architecture and generate test output. In several embodiments, the hardware device(s) 120, 122 may include various devices, such as, but not limited to, FPGAs, as further described below. For example, FPGA(s) may be physically connected to the network to accept and process software backend commands (e.g., job order data 314). In some embodiments, FPGA(s) may be physically connected to boards/controllers to program devices to run software backend commands (e.g., job order data 314). In some embodiments, FPGA(s) may be physically connected to boards/controllers to capture digital output (e.g., hardware output data 230) and send over the network. In some embodiments, FPGA(s) may include emulate peripheral devices to drive/be driven by controllers. In some embodiments, the software backend may drive I/O pins on boards/controllers to communicate with other physical devices.

In the illustrated embodiments of FIGS. 2-3, the various components including (but not limited to) the processing modules 204, 302, the communication module 214 and the network interface 308 are represented by separate boxes. The graphical representations depicted in each of FIGS. 2-4 are, however, merely examples, and are not intended to indicate that any of the various components of the client device(s) 104, 108, 112, or the virtual prototyping management server 118 are necessarily physically separate from one another, although in some embodiments they might be. In other embodiments, however, the structure and/or functionality of any or all of the components of the client device(s) 104, 108, 112, may be combined. In addition, in some embodiments the communication module 214 may include its own processor, volatile memory, and/or non-volatile memory. Likewise, the structure and/or functionality of any or all of the components of the virtual prototyping management server 118 may be combined. In addition, in some embodiments the network interface 308 may include its own processor, volatile memory, and/or non-volatile memory. In addition, the communication module 214 and the network interface 308 may comprise (but is not limited to) one or more transceivers and/or wireless antennas (not shown) configured to transmit and receive wireless signals such as (but not limited to) satellite, radio frequency (RF), Bluetooth or WIFI. In other embodiments, the communication module 214 and the network interface 308 may comprise (but are not limited to) one or more transceivers configured to transmit and receive wired signals.

Although specific systems for virtual prototyping using virtual prototyping platforms are discussed above with respect to FIGS. 1-3, any of a variety of systems including a variety of client devices, servers, hardware devices, communicating using various communication protocols as appropriate to the requirements of a specific application can be utilized in accordance with embodiments of the invention. Processes using virtual prototyping platforms in accordance with embodiments of the invention are discussed further below.

### Processes Using Virtual Prototyping Platforms

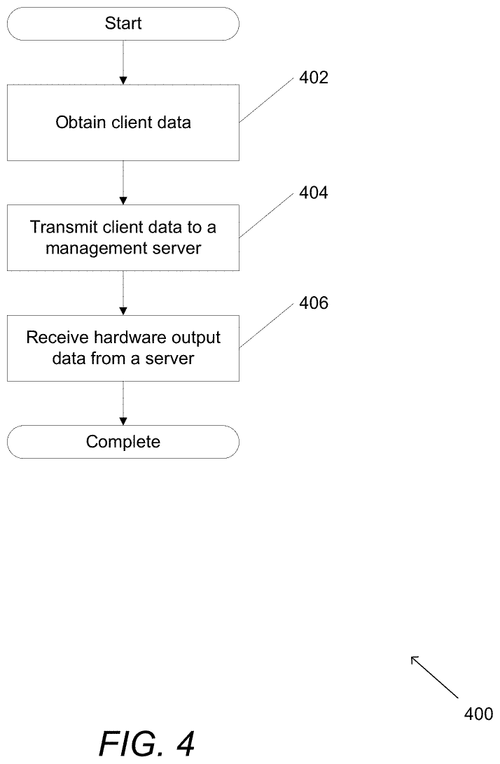

A flow chart illustrating a process for a client device in virtual prototyping in accordance with an embodiment of the invention is shown in FIG. 4. The process 400 may include obtaining (402) client data. In some embodiments, the client device may include an architecture interface where a user may graphically design a physical system using elements such as, but not limited to, drag-and-drop. Further, the architecture interface may include a board/controller, one or more peripheral devices, and/or I/O pin mappings of peripherals to boards. In some embodiments, the client device may include a code interface that allows the client device to obtain (202) source code from the user to run on his/her architected system. In some embodiments, the code interface may include various developer features such as, but not limited to, a standard integrated development environment (IDE) and integration with other software (e.g., Github). In many embodiments, the user may build code using a build service on the client device. In various embodiment, the client device (or the server) may use the architecture information to dynamically build targeting the correct hardware devices.

In reference to FIG. 4, the process 400 may also include transmitting (404) client data to a software backend (e.g., virtual prototyping management server). For example, the user may initiate a “job” via an API call to job service and the client device may transmit the architecture information to the management server. In some embodiments, the client device may be configured to obtain additional information (e.g., test data) about test output to capture. In addition, the process 400 may also include receiving (406) hardware output data from the management server, as further described herein. In many embodiments, the client device may include a test output view interface that allows the user to visualize test output from an executed job. In such embodiments, the user may select a completed job and view metadata such as, but not limited to, start and/or end times. In some embodiments, the test output interface may also present I/O channels that were configured to be captured as viewable waveforms allowing the user to scroll across time, zoom in and/or out, etc. Further, the user may be presented with protocol-level analyzers and/or aggregators for ease of debugging. In many embodiments, the client device may receive (406) the output data from the server dynamically and the data may be sequenced as fixed-chunk pages. In some embodiments, the client device may retrieve pages and caches appropriately for a seamless user experience while also limiting memory consumption. In addition, the client device may also present certain peripheral devices in the system that are software simulated where test output data may be used to run simulations.

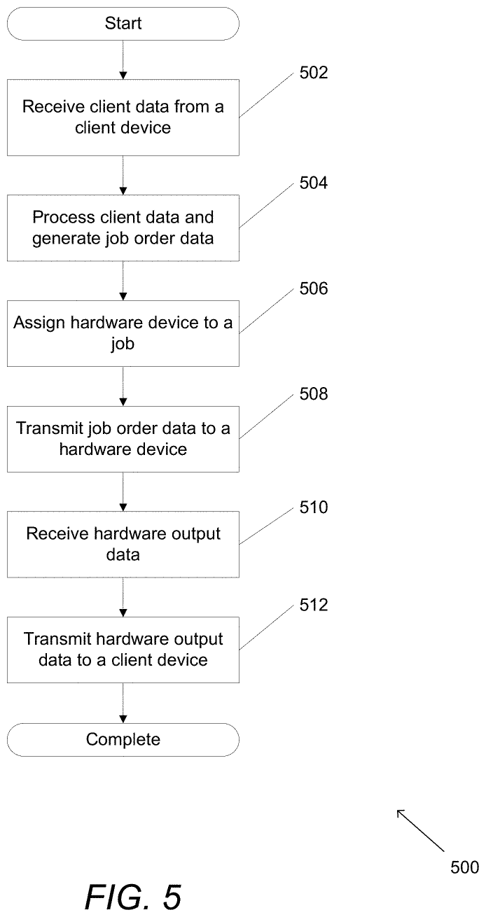

A flow chart illustrating a process for a management server in accordance with an embodiment of the invention is shown in FIG. 5. The process 500 may include receiving (502) client data from one or more client device(s). In some embodiments, a management server may provide a job service configured to interface with a client device to accept new tests to run on one or more hardware device(s). In some embodiments, the job service interface may include receiving architecture information to build a system, code information to run on the system, and/or test information about test output to track. In some embodiments, the job service interface may allow for queuing of jobs until a particular hardware device is available. Further, it may execute an FPGA build to configure an underlying FPGA (or any other hardware device) appropriately. In some embodiments, the build to configure an underlying FPGA may be based on the necessary emulated peripheral devices. In some embodiments, the management server may include a job server that may program and configure FPGAs based on the user's desired pin mappings, test output, etc. In various embodiments, the management server may provide a program controller configured to run a user's source code. In some embodiments, the job server may provide job status updates throughout a process and/or allow for users to manually terminate a job at any point.

In reference to FIG. 5, the process 500 may also include processing (504) client data and generating (504) job order data. In several embodiments, the management server may provide a device service configured to manage provision of hardware device(s) to jobs. In some embodiments, the device service may include tracking hardware devices for availability, where the hardware devices may be located at various location such as, but not limited to, data centers. Further, the device service may obtain locks for available hardware devices based on device types. In some embodiments, the device service may translate high-level commands for FPGAs to proper network protocol format including, but not limited to, programming an FPGA, configuring an FPGA, and/or programming a controller. The process 500 may also include assigning (506) one or more hardware device(s) to a job and transmitting (508) the job order data to a hardware device. For example, the management server may provide a network service configured to manage a network of hardware devices. In some embodiments, the network service may include provisioning MAC/IP addresses, mapping to URIs that the device service consumes, receive payloads and packetize per desired networking protocol, and/or physically transmit packets to hardware devices on the network.

In further reference to FIG. 5, the process 500 may include receiving (510) hardware output data from one or more hardware device(s). In many embodiments, the management server may include a collector service that allows for capturing (may also be referred to as “receiving”) test output (e.g., hardware output data) from one or more hardware device(s). In some embodiments, the collector service may listen in on the network for relevant test output packets. It may also apply metadata to test output such that it can be mapped to the correct job. Further, it may compress data as necessary. In some embodiments, the collector service may also transmit test output with metadata to an output service such that it can be made available to users, as further described below. The process 500 may also include transmitting (512) hardware output data to a client device. In many embodiments, the management server may provide an output service configured to interface with client device(s) to present test output from jobs. In various embodiments, the output service may capture test output from the collector service and store it persistently. In some embodiments, the management service may be configured for storage management to ensure efficient storage utilization. In several embodiments, the management service may allow users to query for test output where a test output may be broken out into fixed-sized “pages” of data and a single query may return a single page.

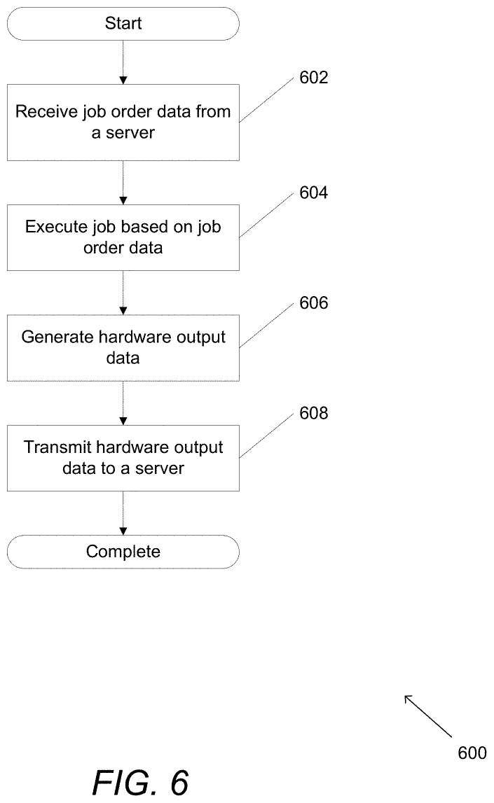

A flow chart illustrating a process for a hardware device in accordance with an embodiment of the invention is shown in FIG. 6. In many embodiments, hardware device(s) may include arbitrary board/controller combinations and/or peripheral devices that may be physically connected via I/O to one or more FPGAs. In various embodiments, FPGAs may be configured to control user devices. In some embodiments, FPGAs may be configured such that all I/O to and/or from user devices may be physically proxied through the FPGA where it may be connected to one or more user devices. In some embodiments, FPGAs may be physically connected to the network and have logic to receive and/or send UDP/IP packets. In some embodiments, the FPGAs may probe on I/O of user devices at a fixed sampling frequency to generate test output data. In some embodiments, FPGAs may act as a set of emulated peripheral devices that may drive and/or accept I/O from the user devices. In some embodiments, the FPGAs may act as a user device itself.

In reference to FIG. 6, the process 600 may include generating (606) hardware output data and transmitting (608) the hardware output data to a management server. In various embodiments, the hardware devices may be part of a network that connects all of the one or more hardware devices, either separately located or part of a data center, to a software controller. In some embodiments, the software controller may be part of the management server, as described above. In some embodiments, such networks may be Ethernet-based with simple unmanaged switches. In some embodiments, such networks may be a star topology centered around SW controllers, as further described below. In such embodiments, the network may include dedicated physical links to Internet (from SW controllers) where hardware devices may be evenly distributed across star. In some embodiments, such networks may be virtual networks that may allow for each star to be “centered” by a virtual machine.

Although specific processes for virtual prototyping systems are discussed above with respect to FIGS. 4-6, any of a variety of processes and variations of the described processes as appropriate to the requirements of a specific application can be utilized in accordance with embodiments of the invention. For example, virtual prototyping systems may provide supplementary client and/or software services and processes. For example, virtual prototyping systems may provide for login, register, verify, reset pages for user account creation and/or management. Further, virtual prototyping systems may allow for integrated with various applications such as, but not limited to, Google, Github, etc. In addition, virtual prototyping systems may provide for authentication services for managing user authentication and/or security, that may include integration with applications such as, but not limited to, Google, Github Oauth. Moreover, authentication services may be a token based authentication scheme. Further, virtual prototyping systems may include project services for managing user projects, that may include integration with applications such as, but not limited to, Github to enforce proper source-version control. Furthermore, virtual prototyping systems may include software build services for executing user software builds targeting available hardware devices. In addition, the software build services may also include submodules for each “class” of software build (e.g., Arduino) and may cache one build per user project. Further, virtual prototyping system may also include FPGA build service for executing FPGA builds that may be for internal use to run FPGA builds for FPGA's in the system dynamically and/or for user use to procure FPGA's as user devices in the system. Virtual prototyping platforms in accordance with embodiments of the invention are further described below.

### Virtual Prototyping Platforms

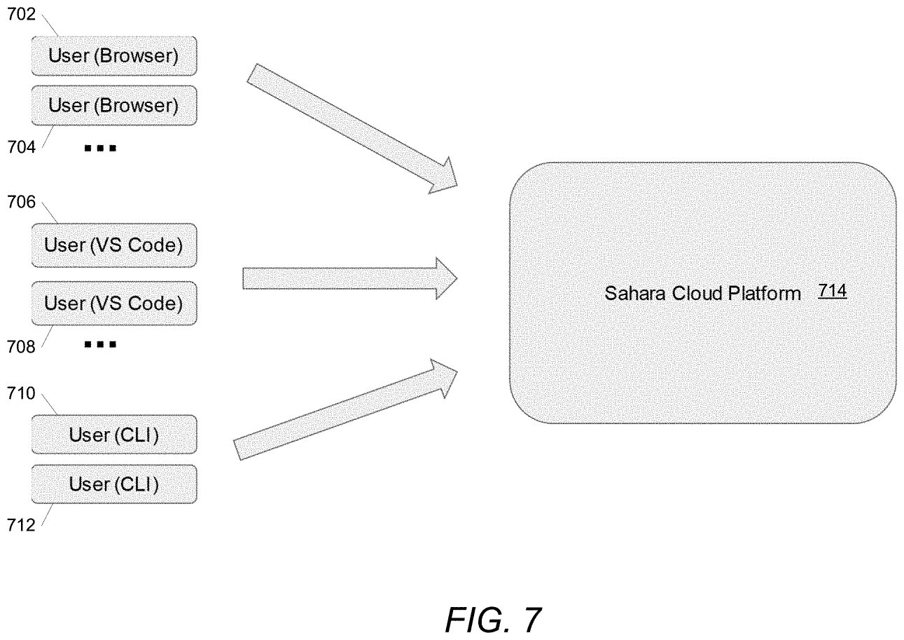

A diagram illustrating user access to a virtual prototyping platform in accordance with an embodiment of the invention is shown in FIG. 7. In many embodiments, users may interact with the virtual prototyping platform 714 (may also be referred to as the “Sahara Cloud platform”) in 3 primary modes: via a web browser (“Browser”) 702, 704, a local integrated development environment (“VS Code”) 706, 708, and/or a command-line interface (“CLI”) 710, 712. In a browser-based environment, users may navigate a graphical user interface (“GUI”) via web pages that are hosted by the management server and/or hosted by a third-party provider. In such embodiments, no specific virtual prototyping software must be installed. In the VS Code environment, users may interact with their project resources in a widely-used IDE among software developers. In some embodiments, the management server may provide a VS Code extension that may facilitates a very similar GUI to that of the web mode of engagement. In some embodiments, the CLI may be a virtual prototyping specific software library that may be installed by advanced users to streamline access to virtual prototyping services by eliminating the GUI. In some embodiments, the CLI may be an application peripheral interface (API) that advanced users can query at their own pleasure. As illustrated and suggested in FIG. 7, an indefinite number of users across various modes of engagement may consume the Sahara Cloud platform 714 concurrently.

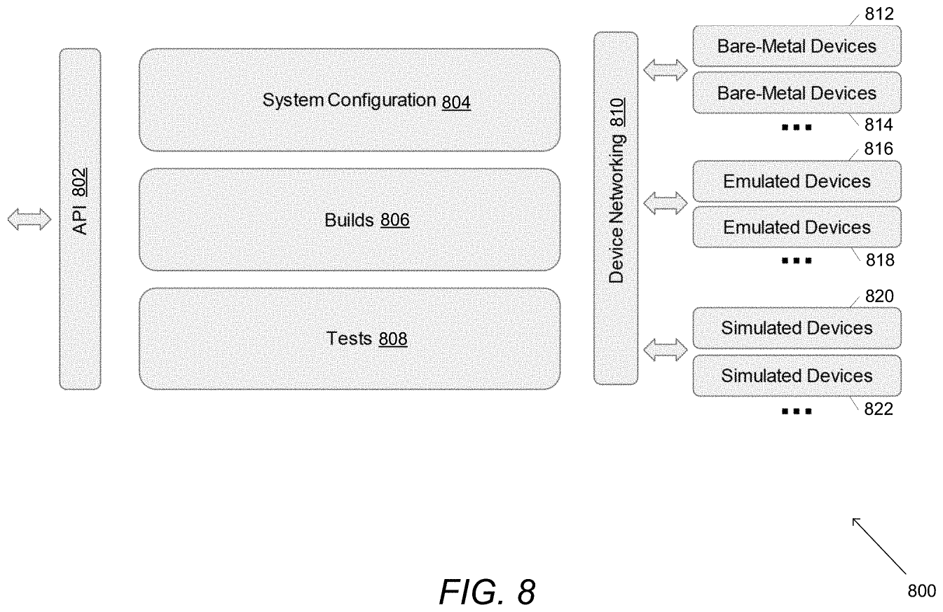

A diagram illustrating a virtual prototyping platform in accordance with an embodiment of the invention is shown in FIG. 8. The Sahara Cloud platform 800 may be gated by an API 802 by which client devices may send requests to consume virtual prototyping services and data, as described herein. In many embodiments, requests via the API 802 may trigger one or more of three software modules (e.g., System Configuration module 804, Builds module 806, and Tests module 808) to take action. In various embodiments, the Sahara Cloud platform 800 may include a device network that may include various devices (may also be referred to as “hardware devices”) such as, but not limited to, bare-metal device(s) 812, 814, emulated device(s) 816, 818, and/or simulated device(s) 820, 822. In a variety of embodiments, the various devices may be connected and/or communicate via device networking 810.

In reference to FIG. 8, the first module may be a System Configuration module 804. This module 804 may handle the logical provisioning of user system runs (i.e., jobs) to the device network 810. Included in this may be the ability to procure and configure the devices (e.g., bare-metal device(s) 812, 814, emulated device(s) 816, 818, and/or simulated device(s) 820, 822) for running a user's job such that it runs correctly, reliably, and efficiently. In addition, this module 804 may be responsible for quality of service (“QoS”) across all concurrent users and jobs, as further described below.

In further reference to FIG. 8, the second module may be a Build module 806. In various embodiments, this module 806 may be responsible for taking user code and its underlying (arbitrary) target architecture and compiling the code such that it can run on that target architecture (e.g., the architecture of the bare-metal device(s) 812, 814, emulated device(s) 816, 818, and/or simulated device(s) 820, 822), as further described below.

In further reference to FIG. 8, the third module may be a Test module 808. This module 808 may present the output data of user jobs in a manner that may be consumed effectively by client devices and/or client applications. The module 808 may also facilitate the collection and/or formatting of raw output data from the device network 810, as further described below. In some embodiments, the device network 810 may act as an interface between the system-level software and the actual devices (e.g., the hardware devices such as, but not limited to, the bare-metal device(s) 812, 814, emulated device(s) 816, 818, and/or simulated device(s) 820, 822) that run jobs and produce test output, as further described below.

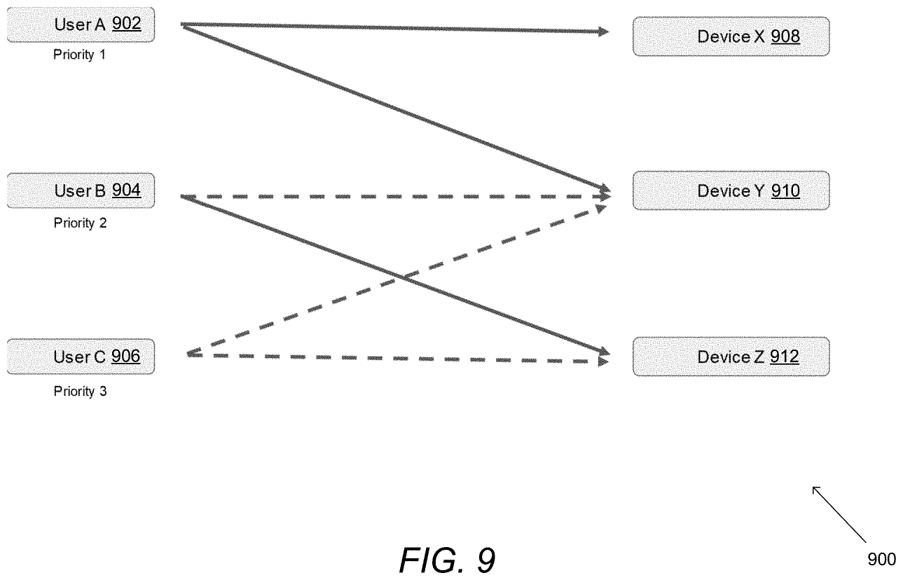

A diagram illustrating a device provisioning system in accordance with an embodiment of the invention is shown in FIG. 9. In many embodiments, the System Configuration module 804 may use a provisioning system 900 to allocate user jobs to underlying devices (e.g., hardware devices). For discussion purposes, the provisioning system 900 may include a plurality of users (e.g., user A 902, user B 904, user C 906) and a plurality of hardware devices (e.g., device X 908, device Y 910, device Z 912). The primary responsibilities of this system 900 may include: 1) correctness 2) quality of service (including no starvation) and 3) performance, as further described below. In some embodiments, correctness may be enforced via a software locking mechanism. For example, each device (e.g., device X 908, device Y 910, device Z 912) on the network may be associated with a semaphore to facilitate its availability. In some cases, (e.g., when the hardware devices are bare-metal devices), the semaphore may be a mutex lock whereby only one user can be using the hardware device for a given time interval. Other hardware devices (e.g., when the hardware devices are simulated devices) have considerably more (or infinite) provisionability. The system 900 may execute queries to capture the current state of the hardware devices and obtain locks if the hardware devices requested are available. Note that a user job may be considered an atomic transaction whereby either all necessary locks are obtained or none are.

In reference to FIG. 9, quality of service may be enforced using both user-level and job-level metadata. User-level metadata such as account type may be used to prioritize those users who have purchased higher service level agreements (SLAs). Job-level metadata such as, but not limited to, time queued may be used to prioritize jobs that have been queued in the system for longer. These priority parameters may be used to resolve collisions in concurrent atomic transactions for hardware devices with finite provisionability. In addition, performance may be another factor that is considered when provisioning jobs to hardware devices. The motivation may be that, especially when dealing with bare-metal devices, physical proximity of the components of the system may become increasingly important. Thus, priority may be dynamically given to available hardware devices that are physically “close” (e.g., in the same sub-network). As illustrated in FIG. 9, users A 902, B 904, and C 906 may have concurrently requested to run jobs. User A's 902 system may comprise devices X 908 and Y 910; user B 904 and C's 906 systems may comprise devices Y 910 and Z 912. During concurrent atomic transactions, it may be deemed that user A's 908 job has the highest priority. Thus, A's 908 job is successfully provisioned while both B 904 and C 906 remain queued (due to atomicity). Upon hardware device release from A 902, B 904, and C 906 may again contend for devices 908, 910, 912. This time, B's 904 priority is deemed higher and thus it procures the devices. User C would continue to wait. Note that starvation is further mitigated by matching demand for hardware device times with supply.

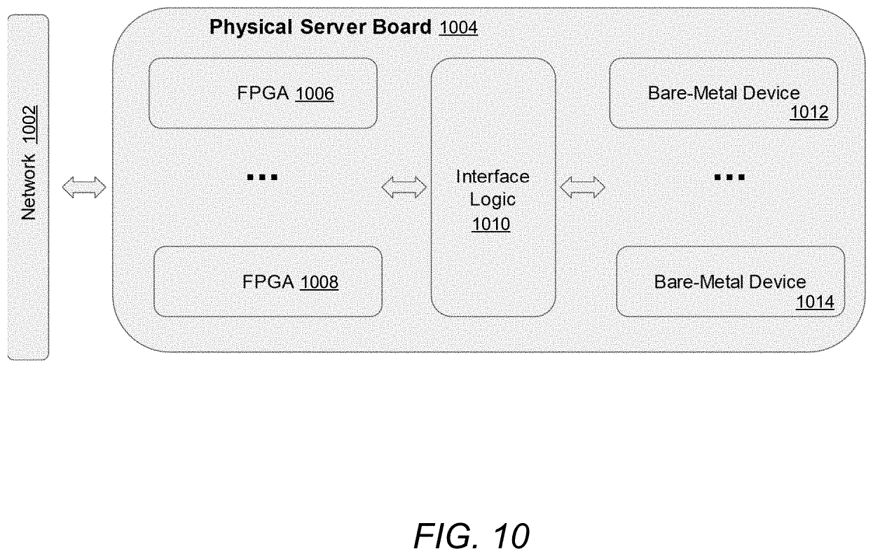

A diagram illustrating emulated and bare-metal devices in accordance with an embodiment of the invention is shown in FIG. 10. Both bare-metal and emulated devices may be facilitated by FPGAs. The FPGA may serve as a bi-directional interface between physical bare-metal devices and the network as well as a target device in of itself. These functions may be multiplexed such that the FPGA may perform both roles at any given time. In many embodiments, a physical server board 1004 may include FPGAs 1006, 1008, an Interface Logic module 1010, and bare-metal devices 1012, 1014. At the bare-metal device level, each FPGA 1006, 1008 may be physically connected both to the network 1002 (e.g., via Ethernet) and to an arbitrary (bounded above) number of bare-metal devices 1012, 1014. Messages from the network 1002 to the bare-metal devices 1012, 1014 may pass through the Interface Logic module 1010 such that they drive the appropriate I/O pins. Similarly, messages from the bare-metal devices 1012, 1014 may pass through the Interface Logic module 1010 such that they can be transmitted over the network 1002, as further described below.

In reference to FIG. 10, if the FPGA (e.g., FPGA 1006 and/or FPGA 108) is acting as an emulated device, it may be able to intercept and act on messages from the network 1002 in isolation (i.e., possibly without passing to any connected bare-metal devices), to generate messages that drive I/O on bare-metal devices, accept stimulus off of I/O from bare-metal devices, and generate messages in isolation to be transmitted on the network 1002, as further described below. Which mode the FPGA 1006, 1008 is acting in may be configurable by software and determined dynamically by the user jobs that need to be serviced. Virtual networks may be used to ensure QoS for configuration messages. In general, there may be many FPGAs (e.g., FPGAs 1006, 1008) and bare-metal devices (e.g., bare-metal devices 1012, 1014) interconnected arbitrarily on the same board (e.g., board 1004). The network may comprise of arbitrarily many of these boards.

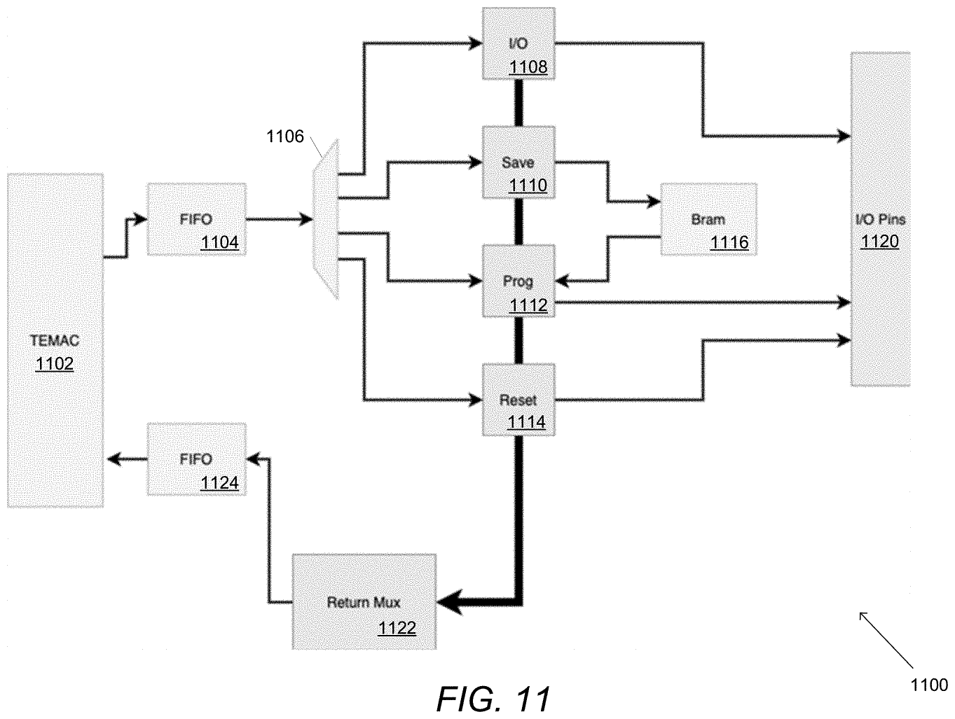

A diagram illustrating a bare-metal FPGA interface (may also be referred to as “Logic Interface” or “Interface Logic”) in accordance with an embodiment of the invention is shown in FIG. 11. In many embodiments, a Logic Interface 1100 between the FPGA and bare-metal devices may act as a message interpreter and transmitter. The TEMAC 1102 may be used to accept/transmit UDP/IP based messages as packets which are pushed to/pulled from first in first out (FIFO) queues 1104, 1124, respectively. For example, the FIFO 1104 may be connected to a data selector (e.g., a demux 1106) that may be connected to various functions/modules such as, but not limited to, I/O 1108, Save 1110, Program 1112, Reset 1114. In some embodiments, the Save 1110 may be connected to a memory (e.g., a BRAM 1116). In some embodiments, the BRAM 1116 may be in connected the Program 1112. In some embodiments, the I/O 1108, Program 1112, and Reset 1114 may be connected to I/O Pins 1120 of the bare-metal devices. In some embodiments, the I/O 1108, Save 1110, Program 1112, and Reset 1114 may also be connected to a Return Mux 1122 that is connected to the FIFO 1124. Messages may be interpreted to take a variety of actions. For example, some messages may allow the network to interface with on-FPGA memory such that data can written (e.g., to program the FPGA) or read (e.g., buffered I/O from bare-metal devices). Other messages may allow for direct interaction with connected bare-metal devices via I/O, either to drive or capture stimuli on their pins.

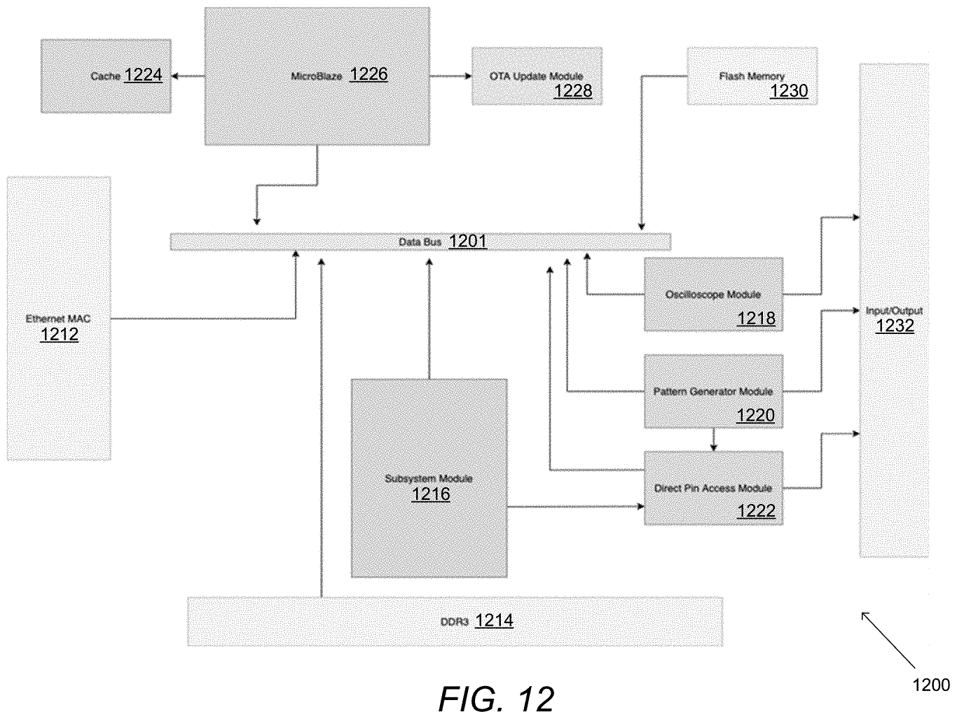

A diagram illustrating a hybrid bare-metal/emulation FPGA interface in accordance with an embodiment of the invention is shown in FIG. 12. The interface 1200 may include a software processor 1226, including but not limited to, a so-called MicroBlaze module 1226 connected to a cache 1124 and an over-the-air (“OTA”) Update module 1228, as further described below. The MicroBlaze module 1226 may also be connected to a data bus 1201. The interface 1200 may also include an Ethernet MAC 1212 that may be connected to the data bus 1201. Further, the interface 1200 may include a memory (e.g., flash memory 1230 and DDR3 1214) connected to the data bus 1201. Moreover, the interface 1200 may also include a Subsystem module 1216 that may be connected to the data bus 1201 and a direct pin access module 1222, as further described below. In some embodiments, the interface 1200 may include an oscilloscope module 1218 that may be connected to the data bus 1201 and an input/output 1232 of hardware devices. In addition, the interface 1200 may also include a pattern generator module 1220 that may be connected to the data bus 1201, direct pin access module 1222, and the input/output 1232. In some embodiments, the direct pin access module 1222 may be connected to the input/output 1232.

FIG. 12 expands upon the basic functionality as described above, and encapsulates the ability for the FPGA to act as one or more emulated devices concurrently to a Logic Interface. In addition to the direct pin access functionality described above, there may be a pattern generator module 1220 to drive arbitrarily complex, but finite and repeated, patterns of stimulus on the bare-metal I/O 1232 and an oscilloscope module 1218 to dynamically trigger data capture off of I/O 1232. This may allow users to capture traditional oscilloscope data off of their bare-metal system components for robust electrical verification. Further, the OTA module 1228 may allow for the FPGA to re-programmed on the fly as needed. In addition, the MicroBlaze module 1226 may act as a lightweight processor to parse messages and interact with memory (e.g., cache 1224) driven by relevant firmware.

In further reference to FIG. 12, there may be a Subsystem module 1216 in which an arbitrary number of emulated devices may be present. These emulated devices may consume a standard interface over the shared data bus 1201 to interact directly with both the network and the connected bare-metal devices. In many embodiments, emulated devices may be necessary because there may be certain physical devices that cannot produce relevant stimulus in a remote setting. For example, a system with a temperature sensor must be able to be tested in “dynamic” temperature settings, not the static temperature of a data center or laboratory. By emulating such a device, the user may control the context of the device to suit the needs of system testing.

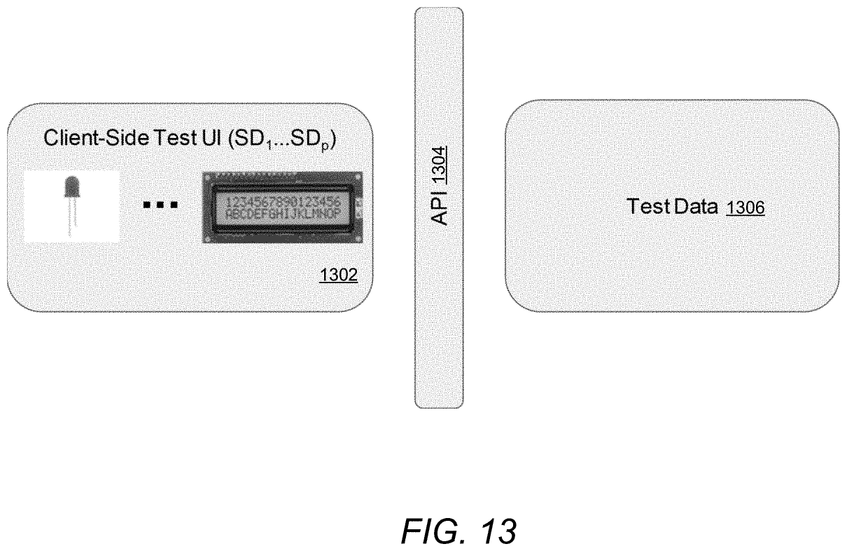

A diagram illustrating simulated devices in accordance with an embodiment of the invention is shown in FIG. 13. In contrast to other hardware device types, simulated devices 1302 may be present on client applications and may thus be relatively unconstrained from a provisioning standpoint. For example, the only constraints may be related to server/CPU usage and relevant provisioning. As such, the client application may send and/or receive stimulus for the device via an API 1304 to the given job's test output such as, but not limited to, test data 1306. In many embodiments, devices that may be best suited for simulation in software are those whose output may be interacted with in a way that requires it being in close physical/virtual proximity to the user and/or user's client device. Examples may include an LED and LCD screen 1302, where users must “see” the output.

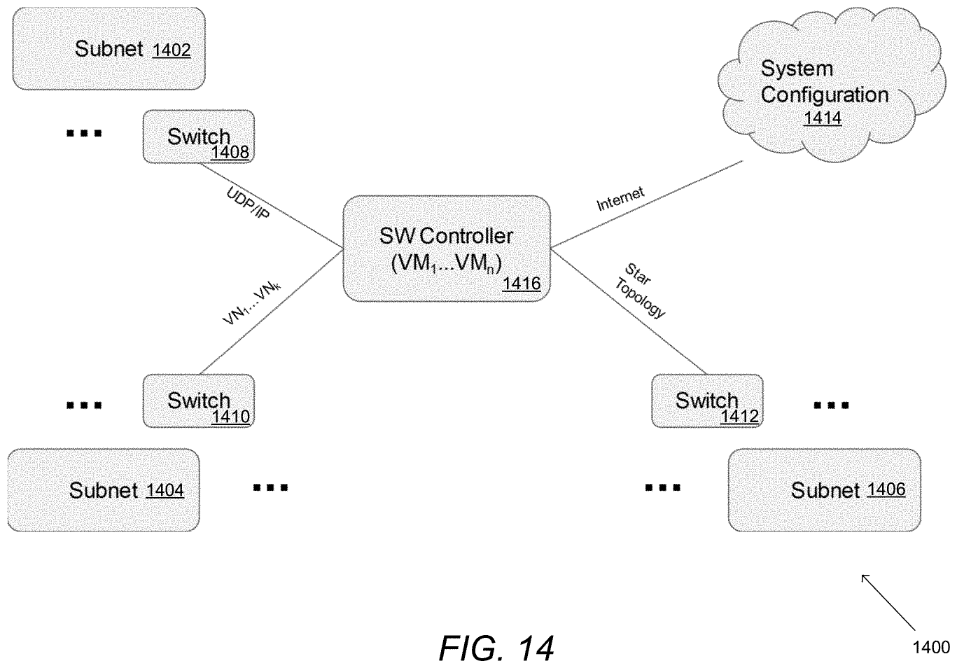

A diagram illustrating a device network in accordance with an embodiment of the invention is shown in FIG. 14. The device network 1400 may include a SW controller 1416 comprising one or more virtual machines (“VM”). In some embodiments, the SW controller 1416 may be connected to a System configuration 1414. In some embodiments, the SW controller 1416 may be connected to one or more switches (e.g., switch 1408, switch 1410, switch 1412) connected to one or more subnets (e.g., subnet 1402, subnet 1404, subnet 1406), respectively. The device network 1400 may illustrate the physical interconnection mechanism between a software platform and FPGAs that gate all bare-metal and emulated devices. In many embodiments, the device network may exist in a data center and/or any other location. In many embodiments, the physical network may be arranged in a traditional star topology. At the center of the star may be a collection of physical servers running core virtual prototyping system software. In some embodiments, each physical server may be further partitioned into multiple VMs. In some embodiments, the VMs may be allocated across the physical network interfaces of their machines. Each physical server may also be a dedicated physical network interface to the Internet such that it may receive and/or send high-level data to the virtual prototyping platform residing in the Cloud.

In reference to FIG. 14, each physical network interface may be multiplexed across multiple virtual networks (“VNs”) to allow for QoS across various message classes and device types as well as appropriate security and/or isolation across user jobs. Each physical network interface may connect to an unmanaged switch which, itself, centers a subnetwork of devices in a star topology. This recursive network structure may continue indefinitely based on the number and breadth of devices in the network. Further, all messages may comply with various network protocols such as, but not limited to, the UDP/IP networking protocol stack. In various embodiments, the topology and protocol may be chosen both to adhere to common network standards and to optimize performance based on the expected traffic pattern. In some embodiments, all messages may be “one-way” and either have a source or destination of one of the VMs at the center of the star. Assuming sufficient and increasing bandwidth as one approaches the center of the star, these design choices may enable optimal average message latency.

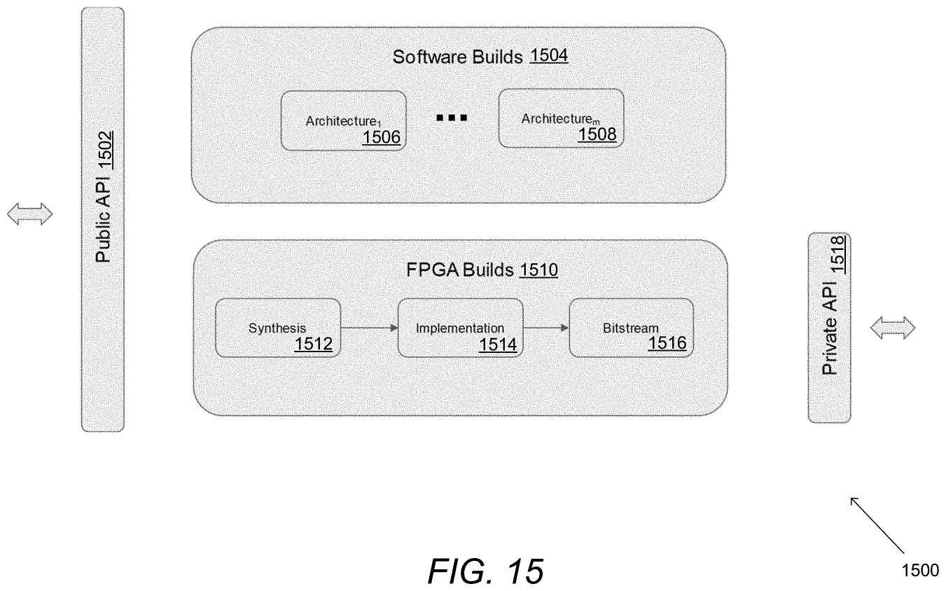

A diagram illustrating a build system in accordance with an embodiment of the invention is shown in FIG. 15. Build software modules may be subdivided into functions such as, but not limited to, builds for user software (e.g., software builds 1504) and builds for FPGAs (e.g., FPGA builds 1510). In several embodiments, user software builds 1504 may target one of a fixed, yet increasing based on the number of devices supported on the platform, set of underlying architectures 1506, 1508. Each unique supported architecture may have its own logic within the software build service to execute compilation from high-level user code, provided by the user, to the necessary low-level constructs to program the target devices. Each logic block may run in parallel and in isolation from the others.

In reference to FIG. 15, FPGA builds 1510 may include those sourced by users and those sourced by the backend virtual prototyping software. As users may allocate FPGAs directly into their systems, they might need to build HDL targeting those FPGAs. For example, this may be enabled via the public API 1502. However, as FPGAs may also be at the core of the underlying virtual prototyping infrastructure, there may be a private API 1518 with high QoS priority for FPGA builds relating to FPGAs used in arbitrary user jobs. The build process may be pipelined across the major steps including, but not limited to, synthesis 1512, implementation 1514, and/or bitstream 1516 generation, for optimal throughput.

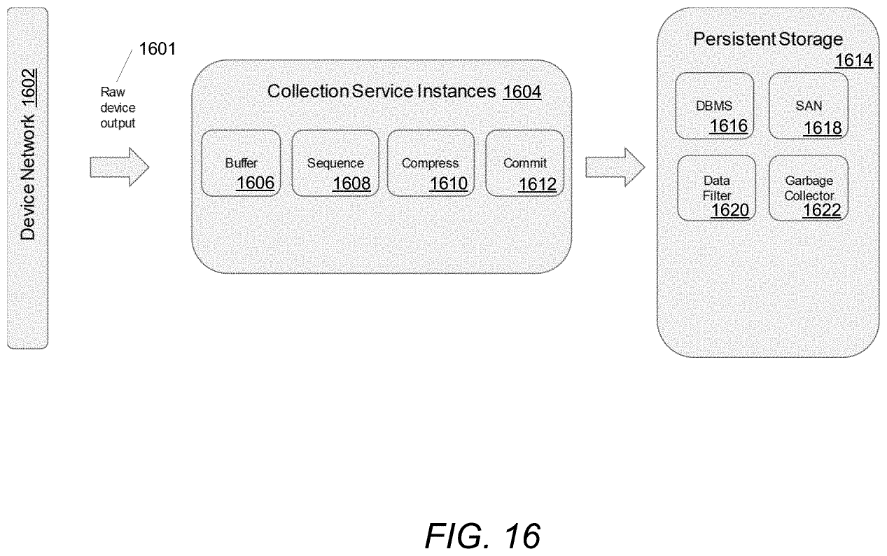

A diagram illustrating test data collection in accordance with an embodiment of the invention is shown in FIG. 16. Running user jobs may be constantly producing raw output 1601, based on user's configuration, which may be captured such that it can be presented back to the user. How that output is captured on-board and transmitted over the network, is further described above. FIG. 16 illustrates how the output data may be processed once it arrives at the virtual prototyping software controller. In many embodiments, the output data 1601 may progress through a pipeline that is optimized for the high throughput that results from high sampling frequencies. For example, raw device output data 1601 (may also be referred to as “raw hardware output data” or “raw data”) may arrive at a collection services instances module 1604 from a device network 1602. In some embodiments, the output data 1601 may be first placed in a large buffer 1606. Placement may trigger a logical sequencing 1608 procedure based on metadata to correct for possible re-ordering on the network. Filled and sequenced buffer data may then be compressed 1610 and subsequently committed 1612 to persistent storage 1614. It is worth noting that high sampling frequencies coupled with the type of raw data captured may enable highly efficient compression ratios with even simple lossless processes.

In reference to FIG. 16, the persistent storage 1614 may be SAN-based 1618 to allow for optimal performance over a scalable amount of physical storage. In many embodiments, software may consume the hardware data via a database management system (DBMS) 1616 that may be relational in nature to allow for optimized queries. In addition, extra care should be given to the necessity of data given the large amounts stored. First, there may be a filtering 1620 mechanism by which only data pertaining to an active job is kept. Second, there may be a garbage collection 1622 mechanism to remove data that is no longer needed. For example, only a fixed number of user jobs may be stored and thus, as new jobs are run, old job data may be deleted.

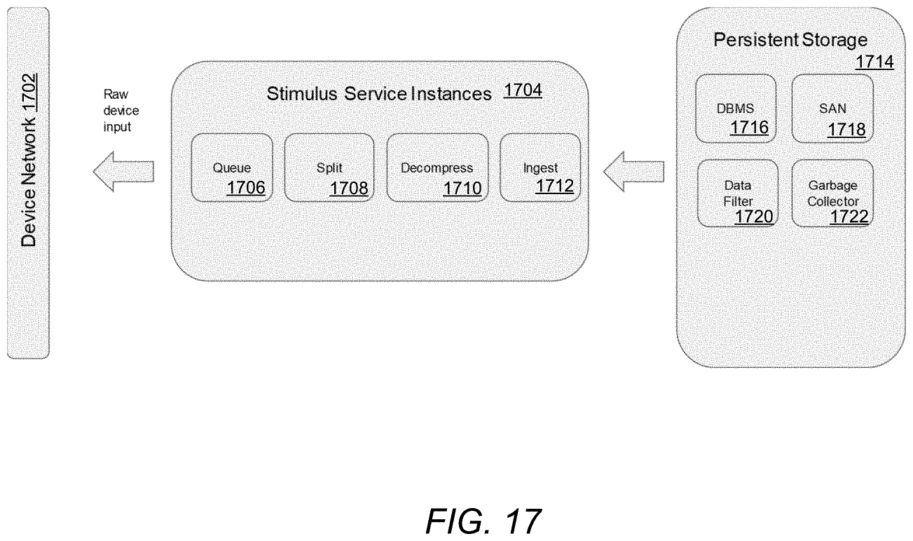

A diagram illustrating test data stimulus in accordance with an embodiment of the invention is shown in FIG. 17. In addition to test output being stored, devices should be able to accept arbitrary user-generated stimulus using a stimulus service instances module 1704. As such, stimulus, as defined in the user jobs, may also be captured in the persistent storage 1714. As described above, persistent storage may include DBMS 1716, SAN-based storage 1718, data filter 1720, and a garbage collector 1722. In many embodiments, data (e.g., stimulus) may proceed through a separate and reverse pipeline of the test data capture, as described above. For example, the reverse pipeline may include data ingesting 1712, decompressing 1710, splitting 1708, and queuing 1706 to push data out to a device network 1702. Processes for how such stimulus is applied to the target devices after traversing the network to its destination, is described above.

Although specific virtual prototyping platforms and virtual prototyping processes are discussed above with respect to FIGS. 7-17, any of a variety of platforms and processes as appropriate to the requirements of a specific application can be utilized in accordance with embodiments of the invention. While the above description contains many specific embodiments of the invention, these should not be construed as limitations on the scope of the invention, but rather as an example of one embodiment thereof. It is therefore to be understood that the present invention may be practiced otherwise than specifically described, without departing from the scope and spirit of the present invention. Thus, embodiments of the present invention should be considered in all respects as illustrative and not restrictive.

What is claimed is:

1. A non-transitory machine readable storage medium storing a program comprising instructions that, when executed by at least one processor of at least one server, cause the server(s) to perform operations including:
receiving, at the server(s), from a client device, architecture data comprising a selection of a hardware device for virtual prototyping;
generating job order data, wherein the job order data provides logical provisioning of at least one hardware device;
transmitting, from the server(s), to the at least one hardware device, the job order data;
receiving, at the server(s), from the at least one hardware device, hardware output data; and
transmitting, from the server(s), to the client device, the hardware output data.

2. The non-transitory computer readable storage medium of claim 1 wherein logical provisioning of the at least one hardware device includes configuring the at least one hardware device to run a job.

3. The non-transitory computer readable storage medium of claim 1 further comprising instructions that, when executed by the at least one processor, further cause the server(s) to receive, at the server(s), from the client device, code data to run on the at least one hardware device.

4. The non-transitory computer readable storage medium of claim 3, wherein the job order data comprises the code data.

5. The non-transitory computer readable storage medium of claim 3 further comprising instructions that, when executed by the at least one processor, further cause the server(s) to identify a target architecture associated with the at least one hardware device and compile the code data such that it can run on the target architecture.

6. The non-transitory computer readable storage medium of claim 5, wherein the job order data comprises the compiled code data.

7. The non-transitory computer readable storage medium of claim 1 further comprising instructions that, when executed by the at least one processor, further cause the server(s) to receive, at the server(s), from the client device, test data comprising information about test output to track.

8. The non-transitory computer readable storage medium of claim 7, wherein the job order data comprises the test data.

9. The non-transitory computer readable storage medium of claim 1, wherein the hardware output data received from the at least one hardware device is raw output data.

10. The non-transitory computer readable storage medium of claim 9 further comprising instructions that, when executed by the at least one processor, further cause the server(s) to format the raw output data prior to transmitting, from the server(s), to the client device, the hardware output data.

11. The non-transitory computer readable storage medium of claim 10, wherein formatting the raw output data comprises:
placing the raw output data in a buffer;
sequencing the raw output data based on metadata associated with the raw output data to correct for re-ordering;
compressing the sequenced raw output data; and
storing the sequenced raw output data in a storage.

12. The non-transitory computer readable storage medium of claim 1, wherein the at least one hardware device includes at least one FPGA.

13. The non-transitory computer readable storage medium of claim 12, wherein the job order data comprises pin mappings for configuring the at least one FPGA.

14. The non-transitory computer readable storage medium of claim 1, wherein the at least one hardware device includes at least one bare-metal device.

15. The non-transitory computer readable storage medium of claim 14 further comprising instructions that, when executed by the at least one processor, further cause the server(s) to procure the at least one bare-metal device based on physical proximity of the at least one bare-metal device to the server(s).

16. The non-transitory computer readable storage medium of claim 14 further comprising instructions that, when executed by the at least one processor, further cause the server(s) to procure the at least one bare-metal device based on a maximum number of current users of the at least one bare-metal device, wherein the at least one bare-metal device includes a lock whereby only one user can use the at least one bare-metal device for a given time interval.

17. The non-transitory computer readable storage medium of claim 1, wherein the at least one hardware device includes at least one simulated device.

18. The non-transitory computer readable storage medium of claim 1, wherein the at least one hardware device includes at least one emulated device.

19. The non-transitory computer readable storage medium of claim 18, wherein the at least one hardware device further includes at least one simulated device.

20. The non-transitory computer readable storage medium of claim 14, wherein the at least one hardware device further includes at least one simulated device.

21. The non-transitory computer readable storage medium of claim 20 wherein the at least one hardware device further includes at least one emulated device.

22. The non-transitory computer readable storage medium of claim 14, wherein the at least one hardware device further includes at least one emulated device.

23. The non-transitory computer readable storage medium of claim 1 further comprising instructions that, when executed by the at least one processor, further cause the server(s) to procure the at least one hardware device by transmitting, from the server(s), to a network of hardware devices, queries to capture the current state of the at least one hardware device and to obtain a lock when the at least one hardware device is available.

24. The non-transitory computer readable storage medium of claim 1 further comprising instructions that, when executed by the at least one processor, further cause the server(s) to prioritize a job based on user-level metadata and job-level metadata.
